(19) United States
(12) Patent Application Publication
(10) Pub. No.: US 2004/0187785 A1
(43) Pub. Date: Sep. 30, 2004

(54) Deposition apparatus and deposition method

(75) Inventors: Katsushi Kishimoto, Soraku-gun (JP); Yusuke Fukuoka, Ikoma-gun (JP); Akira Shimizu, Goze (JP); Katsuhiko Nomoto, Kashihara (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/787,748

(22) Filed: Feb. 27, 2004

(30) Foreign Application Priority Data
Mar. 24, 2003 (JP) 2003-080876

(51) Int. Cl. C23C 16/00

(52) U.S. Cl. 118/719; 427/248.1; 118/723 E

(57) ABSTRACT

The invention provides a deposition apparatus that enables significant reduction in the total gas consumption, simplification of the overall structure of the apparatus, and cost reduction of the apparatus even when feeding gas into a plurality of thin-film formation spacings. The apparatus has a plurality of thin-film formation spacings for forming same thin films. Source-gas feed openings capable of feeding at least a source gas are provided in each of the plurality of thin-film formation spacings. A discharge gas of at least one of the plurality of thin-film formation spacings can be fed into another one of the plurality of thin-film formation spacings through a discharge-gas flow path. A dilution gas is fed into the former thin-film formation spacing, and the discharge gas is discharged to the outside from the external discharge port of the another thin-film formation spacing.

### BACKGROUND OF THE INVENTION

1. Field of the Invention

This invention relates to a deposition apparatus and a deposition method that are used to form thin films, such as semiconductors. More particularly, the invention relates to feeding and discharge of gas in the deposition apparatus and the deposition method.

2. Description of the Related Art

Conventionally, as deposition apparatuses to be used to form thin films such as semiconductor devices, there are plasma reactor apparatuses of the type that feeds a reactant gas into a plurality of discharge spacings in parallel according to a plasma chemistry technique (an example of the plasma reactor apparatus is disclosed in U.S. Pat. No. 4,264,393).

The plasma reactor apparatus disclosed in U.S. Pat. No. 4,264,393 is designed to feed the same reactant gas in the plurality of discharge spacings at the same time. As such, the flow rate of the gas is proportional to a number N of the discharge spacings. For example, where the reactant gas necessary for one of the discharge spacings is SiH₄/H₂=5/500 (sccm), the total flow rate of the gas is SiH₄: 5×N (sccm), H₂: 500×N (sccm).

In addition, deposition methods used to form thin films such as semiconductor devices include those of the type that feeds a reactant gas and a nonreactant gas through different systems (an example method of this type is disclosed in Japanese Unexamined Patent Application Publication No. 04-164895). The method disclosed in the publication is a semiconductor-film epitaxial growth technique characterized in that the reactant gas is injected parallel to or oblique onto a substrate, and a pressing dispersal gas is injected to the substrate. With this deposition method, the technique of feeding the reactant gas and the dispersal gas through different systems has been proposed. In addition, according to the deposition method, epitaxial growth is significantly promoted in the manner that the reactant gas is fed immediately over the substrate in parallel to the substrate, a dispersal gas is injected to the substrate through different systems, thermal residence occurring in association with heating of the substrate is restrained, and the gas is uniformly fed near the substrate. However, the above-described deposition apparatus and the deposition method have problems as described hereunder.

According to the plasma reactor apparatus disclosed in U.S. Pat. No. 4,264,393, while the reactant gas is fed into the plurality of discharge spacings, the reactant gas should be fed sufficient in units of the discharge spacing. In this case, the total gas flow rate is N times the flow rate of the reactant gases per discharge spacing. This results in a significant increase in the flow rate of gas to be processed overall. This involves enlargement in the size of a discharge system construction (in regard to a discharge piping system, valve diameter, and pump discharge capacity, for example), consequently leading to an increase in the apparatus cost. If the reactant gas system is associated with, for example, a gas purification apparatus, enlargement of the processing facility is unavoidable, thereby causing a further cost increase.

With the deposition method disclosed in the Japanese Unexamined Patent Publication No. 04-164895, there has been disclosed a technique that separates gases into a reactant gas and a dispersal gas and that separately feed the gases through the different systems. More specifically, the technique causes a GaN (gallium nitride) to grow over a sapphire having a diameter of 2 inches. (about 50.8 mm). However, in a deposition procedure for, for example, a large-area liquid crystal or solar cells having a substrate area as large as about 1 m square, a central portion of the substrate is spaced apart at several tens of centimeters from an end portion thereof. This makes it difficult for the conventional deposition technique to uniformly feed the reactant gas over the entirety of the substrate.

### SUMMARY OF THE INVENTION

The present invention is aimed to implement effective use of a reactant gas and reduction in the total gas consumption in processing steps for deposition onto large-area substrates of, for example, liquid crystal or solar cells. More particularly, the object of the invention is to provide a deposition apparatus and a deposition method that enable significant reduction in the total gas consumption, simplification of the overall structure of the apparatus, and cost reduction of the apparatus even when feeding gas into a plurality of thin-film formation spacings.

A deposition apparatus of the invention is characterized by comprising a plurality of thin-film formation spacings for forming same thin films, wherein source-gas feed openings capable of feeding at least a source gas are provided in each of the plurality of thin-film formation spacings, and a discharge gas of at least one of the plurality of thin-film formation spacings can be fed into another one of the plurality of thin-film formation spacings. The deposition apparatus of the invention is further characterized in that in addition to the source-gas feed openings, a dilution-gas feed port is provided in only one or a plurality of first thin-film formation spacings provided as a part of the plurality of thin-film formation spacings, and the discharge gas of the first thin-film formation spacing can be fed into at least one of second thin-film formation spacings that is a part of the plurality of thin-film formation spacings and that is not the first thin-film formation spacing. The deposition apparatus of the invention is further characterized in that a dilution gas can be fed to source-gas feed openings of only one or the plurality of first thin-film formation spacings provided as a part of the plurality of thin-film formation spacings, and the discharge gas of the first thin-film formation spacing can be fed into at least one of second thin-film formation spacings that is the part of the plurality of thin-film formation spacings and that is not the first thin-film formation spacing. According to the feature configuration, the dilution gas can be shared between the one of the thin-film formation spacings and another one of the thin-film formation spacings, thereby enabling contribution to reduction in the total gas consumption.

The deposition apparatus of the invention is further characterized in that an external discharge port for discharging the discharge gas to an external portion excluding the plurality of thin-film formation spacings is provided in at least one of the second thin-film formation spacings. According to the feature configuration, only the discharge gas with the dilution gas shared between the one thin-film formation spacing and another one of the thin-film formation spacings is discharged to the outside of the system, thereby enabling the gas consumption to be securely reduced.

In addition, the deposition apparatus of the invention is characterized in that one unit of the first thin-film formation spacing is provided; and one unit of the second thin-film formation spacing is provided wherein the external discharge port is provided. According to the feature configuration, an inlet and an outlet are limited to one, so that the image processing can be most efficiently reduced.

The deposition apparatus of the invention is further characterized in that in a case where the number of the plurality of thin-film formation spacings is three or more, the discharge gas of the second thin-film formation spacing wherein the external discharge port is not provided can be fed to another one of the second thin-film formation spacings. According to the feature configuration, even in the case where the number of the thin-film formation spacings is three or more, the gas consumption can be reduced similarly to the above.

The deposition apparatus of the invention is further characterized in that the source-gas feed openings are provided opposite a depositing plane in the form of plural distributions. Further, each of the plurality of thin-film formation spacings is preferably formed between a cathode electrode and an anode electrode that oppose each other. Further, the source-gas feed openings are preferably provided on the cathode electrode. According to the feature configuration, the arrangement is effective to equalize the feed quantity of the in-plane source gas (including the dilution gas) significantly influencing the film thickness and the film quality. Further, when each of the plurality of thin-film formation spacings is formed between a cathode electrode and an anode electrode that oppose each other, the thin film formation using plasma reactions can be implemented.

According to the deposition apparatus of the invention, either when the plurality of thin-film formation spacings are formed in one reaction chamber or when each of the thin-film formation spacings is separately formed in one reaction chamber, similar operation effects according to the feature configuration can be exhibited.

A deposition method of the invention parallely forms same thin films in a plurality of thin-film formation spacings. This deposition method is characterized in that at least a source gas is fed into each of the plurality of thin-film formation spacings, and a discharge gas of at least one of the plurality of thin-film formation spacings is fed into another one of the plurality of thin-film formation spacings. In addition, the deposition method of the invention is characterized in that in addition to the source gas, a dilution gas is fed into only one or a plurality of first thin-film formation spacings provided as a part of the plurality of thin-film formation spacings, and the discharge gas of the first thin-film formation spacing is fed into at least one of second thin-film formation spacings that is a part of the plurality of thin-film formation spacings and that is not the first thin-film formation spacing. The deposition method of the invention is further characterized in that a gas mixture of the source gas and a dilution gas is fed into only one or a plurality of first thin-film formation spacings provided as a part of the plurality of thin-film formation spacings, and the discharge gas of the first thin-film formation spacing is fed into at least one of second thin-film formation spacings that is a part of the plurality of thin-film formation spacings and that is not the first thin-film formation spacing. Further, the deposition method of the invention is characterized in that the discharge gas of one or the plurality of first thin-film formation spacings is fed into at least one of second thin-film formation spacings that is a part of the plurality of thin-film formation spacings and that is not the first thin-film formation spacing, and a flow rate of a gas containing at least the source gas to be fed into the first thin-film formation spacing and a concentration of the source gas are different from a flow rate of a gas containing at least the source gas to be fed into the second thin-film formation spacing, to which the discharge gas of the first thin-film formation spacing is fed, and a concentration of the source gas. According to the feature deposition method of the invention, the dilution gas can be shared between the one of the thin-film formation spacings and another one of the thin-film formation spacings, thereby enabling contribution to reduction in the total gas consumption.

Furthermore, the deposition method of the invention is characterized in that the discharge gas is discharged from at least one of the second thin-film formation spacings to an external portion excluding the plurality of thin-film formation spacings. According to the feature deposition method of the invention, only the discharge gas with the dilution gas shared between the one of the thin-film formation spacings and the another one of the thin-film formation spacings is discharged to the outside of the system, thereby enabling the gas consumption to be securely reduced.

### BRIEF DESCRIPTION OF THE DRAWINGS

In the accompanying drawings:

FIG. 1 is a schematic vertical cross-sectional view of a first embodiment of a deposition apparatus according to the invention;

FIG. 2 is a schematic vertical cross-sectional view of a second embodiment of a deposition apparatus according to the invention; and

FIG. 3 is a schematic vertical cross-sectional view of a third embodiment of a deposition apparatus according to the invention.

### DETAILED DESCRIPTION OF THE INVENTION

Referring to the drawings, a description will be made regarding embodiments of a deposition apparatus and a deposition method (which hereinbelow will be referred to as an “inventive apparatus” and an “inventive method,” respectively, in appropriate portions) of the invention.

### First Embodiment

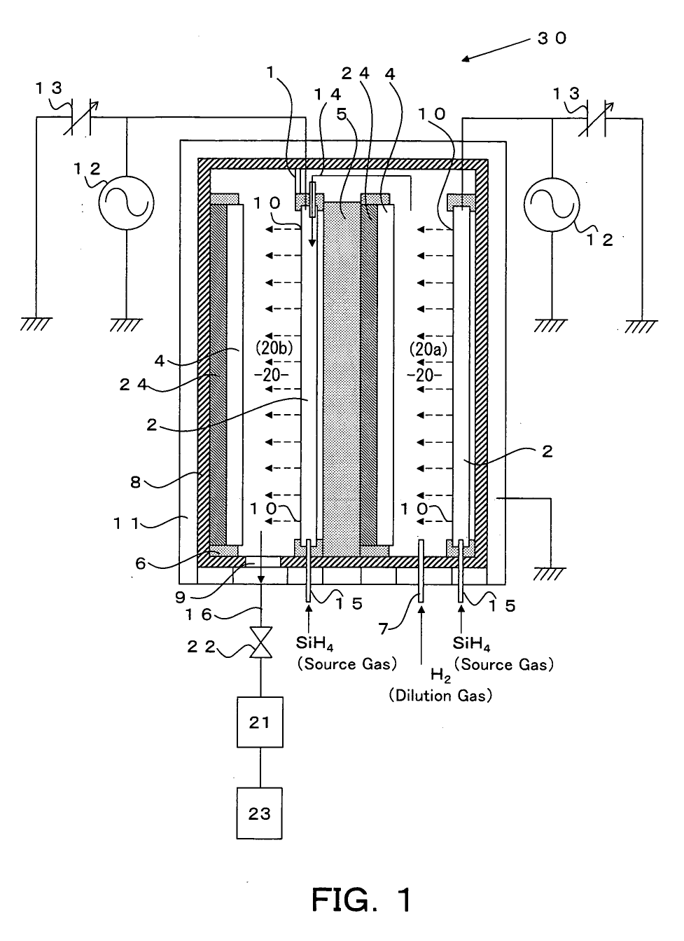

A first embodiment of a deposition apparatus of the invention will be described with reference to FIG. 1. FIG. 1 is a schematic vertical cross-sectional view of an inventive apparatus 30.

Referring to FIG. 1, in the configuration of the inventive apparatus 30, a plurality of thin-film formation spacings 20 (two spacings in the first embodiment) are formed by providing a plurality of discharge spacings each sandwiched by a cathode electrode 2 and an anode electrode 4 in a same chamber 11 (reaction chamber). Source-gas feed openings 10 are provided in each of the thin-film formation spacings 20, and a dilution-gas feed port 7 for introducing a dilution gas is provided in the thin-film formation spacing 20 (first thin-film formation spacing 20a) on one side. Thereby, a discharge gas of the first thin-film formation spacing 20a is feedable into the thin-film formation spacing 20 (second thin-film formation spacing 20b) on the other side through a discharge-gas flow path 14. In addition, in the configuration, a discharge gas of the second thin-film formation spacing 20b is discharged to the outside of the system from an external discharge port 9 provided in the second thin-film formation spacing 20b through discharge piping 16 via a pressure control unit 22, a vacuum pump 21, and a gas purification apparatus 23. The configuration will be described hereinbelow in more detail.

The chamber 11 (reaction chamber) is formed of stainless steel or an aluminium alloy. Connected or fitted portions of the chamber 11 are completely sealed by 0-rings or the like components. The discharge piping 16, the pressure control unit 22, and the vacuum pump 21 are connected to the chamber 11. Thereby, the vacuum level in the chamber 11 can be controlled to an arbitrary level. The gas purification apparatus 23 is connected to the downstream side of the vacuum pump 21 to remove deleterious substances contained in the discharge gas after reaction with the reactant gas (source gas) introduced into the chamber 11.

An anode support 6 for supporting the anode electrode 4 is disposed in a bottom portion of the chamber 11. For the material of the anode support 6, conductive stainless steel or aluminium alloy may be used, but an insulation component (such as a ceramic material) may be used to control the potential of the substrate.

The anode electrode 4 is formed of a material having conductivity and heat resistance, such as stainless steel, aluminium alloy, or carbon. The size dimensions of the anode electrode 4 are determined to be appropriate values in accordance with the size dimensions of a glass substrate that used to firm the thin film. In this particular embodiment, the anode electrode 4 is designed to have the size dimensions of (long side×short side: (1,000-1,500 mm)×(600-1,000 mm)) with respect to the size dimensions of the substrate of (900-1,200 mm)×(400-900 mm).

The anode electrode 4 has a built-in a heater 24 on the back face with respect to the thin-film formation spacing 20. Using the heater 24, the anode electrode 4 is heated and controlled to fall within the range of from a room temperature to 300° C. In the present embodiment, the anode electrode 4 uses a device consisting of, for example, an enclosed heating device, such as a sheath heater, and an enclosed temperature sensor, such as a thermocouple, which are built in the aluminium alloy. With these devices being used, the anode electrode 4 is heated and controlled to fall within the range of from the room temperature to 300° C.

The cathode electrode 2 has a function of a shower plate, in which a plurality of shower openings (source-gas feed openings 10) are distributed on the surface on the side opposite to the anode electrode 4. In this configuration, the source gas is fed to the cathode electrode 2 from a source gas inlet 15 provided to introduce the source gas into the cathode electrode 2 (shower plate) from the outside. Thereby, the introduced source gas can be uniformly dispersed and fed into the thin-film formation spacing 20 from the source-gas feed openings 10. The cathode electrode 2 is connected with a plasma-exciting high-frequency power source 12 and an impedance matching unit 13.

The case of forming a non-monocrystaline Si crystal film in accordance with the inventive method using the inventive apparatus 30 will now be described hereinbelow.

The source gas is introduced into the individual thin-film formation spacings 20 from the plurality of the shower openings (source-gas feed openings 10) provided in the individual cathode electrode 2. In this event, the source gas (SiH₄ gas) is fed to the first thin-film formation spacing 20afrom the shower plate 2. The dilution gas (H₂) is, however, fed from the dilution-gas feed port 7 in a different system, and the fed gas to be fed into the second thin-film formation spacing 20b is limited only to the source gas (SiH₄ gas).

An optimal condition for forming the non-monocrystalline Si crystal film is a gas ratio of SiH₄/H₂=1-10/300 (sccm), for example. In this case, the source gas is SiH₄, and substantially 100% SiH₄ (source gas) is consumed, so that the discharge gas of the first thin-film formation spacing 20a can be contemplated to be only H₂ (dilution gas). As such, in the configuration, a partition 1 is provided to limit the discharge-gas flow path 14, and the source gas inlet 15 is provided also in the thin-film formation spacing 20b that introduces the source gas into the cathode electrode 2 (shower plate) from the outside. Using this configuration, the source gas (SiH₄ gas) is supplementarily fed into the shower plate 2 to compensate for the consumed part of the source gas. In this configuration also, the dilution-gas feed port 7 is provided only on the side of the first thin-film formation spacing 20a, and the external discharge port 9 for discharging the discharge gas to the outside of the system is provided only on the side of the second thin-film formation spacing 20b. The configuration thus arranged enables the dilution gas in the first thin-film formation spacing 20a to be shared in the second thin-film formation spacing 20b, so that the use quantity of the dilution gas can be significantly reduced.

### Second Embodiment

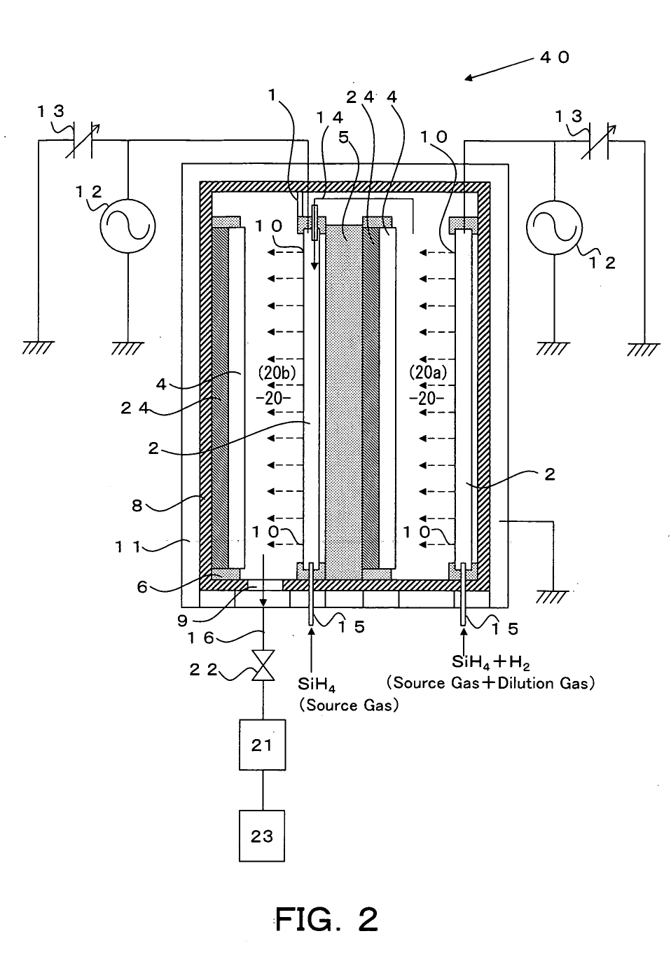

A second embodiment of a deposition apparatus of the invention will be described with reference to FIG. 2. FIG. 2 is a schematic vertical cross-sectional view of an inventive apparatus 40. Portions common to those in FIG. 1 will be described using the same reference numerals.

As shown in FIG. 2, the inventive apparatus 40 has the basic configuration common to the inventive apparatus 30 of the first embodiment. That is, a plurality of thin-film formation spacings 20 (two spacings in the second embodiment) are formed by providing a plurality of discharge spacings each sandwiched by a cathode electrode 2 and an anode electrodes 4 in a same chamber 11 (reaction chamber). Source-gas feed openings 10 are provided in each of the thin-film formation spacings 20, and a discharge gas of the thin-film formation spacing 20 (first thin-film formation spacing 20a) on one side is feedable into the thin-film formation spacing 20 (second thin-film formation spacing 20b) on the other side through a discharge-gas flow path 14. In addition, in the configuration, a discharge gas of the second thin-film formation spacing 20b is discharged to the outside of the system from an external discharge port 9 provided in the second thin-film formation spacing 20b through discharge piping 16 via a pressure control unit 22, a vacuum pump 21, and a gas purification apparatus 23. A difference from the first embodiment is that a dilution-gas dedicated feed port is not separately provided in the first thin-film formation spacing 20a.

In the second embodiment, a description will be provided regarding the case of forming an amorphous Si film in accordance with the inventive method using the inventive apparatus 40.

When forming the amorphous Si film, the source gas is introduced into the individual thin-film formation spacings 20 from the plurality of the shower openings (source-gas feed openings 10) provided in the individual cathode electrode 2. In this case, the source gas (SiH₄ gas) is fed to the first thin-film formation spacing 20a from the shower plate 2. An optimal condition for forming the amorphous Si film is a gas ratio of SiH₄/H₂=30-300/300 (sccm), for example. Under the condition, when, as in the case of the first embodiment, the dilution gas is fed from the periphery of the thin-film formation spacing 20 in the first thin-film formation spacing 20a, only 10-20% source gas (SiH₄) of that gas is consumed. Thereby, a stationary gas concentration gradient is build up toward the side of the discharge port (discharge-gas flow path 14) from the side of the dilution-gas feed port 7. This causes the source gas (SiH₄ gas) of a high concentration to exist on the side of the discharge port, thereby disabling uniform in-plane deposition. For this reason, as shown in FIG. 2, when forming the amorphous Si film, a gas mixture (SiH₄+H₂) of the source gas and the dilution gas is used as the gas to be fed to the first thin-film formation spacing 20a, and the gas mixture is uniformly fed from the shower plate 2 in the plane.

Then, suppose that the discharge gas of the first thin-film formation spacing 20a is used as a feed gas to be fed into the second thin-film formation spacing 20b. In this case, as the feed gas to the second thin-film formation spacing 20b, the source gas (SiH₄ gas) may be supplemented to the discharge gas of the first thin-film formation spacing 20a to compensate for the part consumed in the first thin-film formation spacing 20a. As such, in the configuration, a partition 1 is provided to limit the discharge-gas flow path 14, and the source gas inlet 15 is provided also in the thin-film formation spacing 20b that introduces the source gas into the cathode electrode 2 (shower plate) from the outside. Using this configuration, the source gas (SiH₄ gas) is supplementarily fed into the shower plate 2 to compensate for the consumed part of the source gas.

In the second embodiment also, the external discharge port 9 for discharging the discharge gas to the outside of the system is provided only on the side of the second thin-film formation spacing 20b. The configuration thus arranged enables the dilution gas in the first thin-film formation spacing 20a to be used also in the second thin-film formation spacing 20b. Consequently, the use quantity of the dilution gas can be significantly reduced.

### Third Embodiment

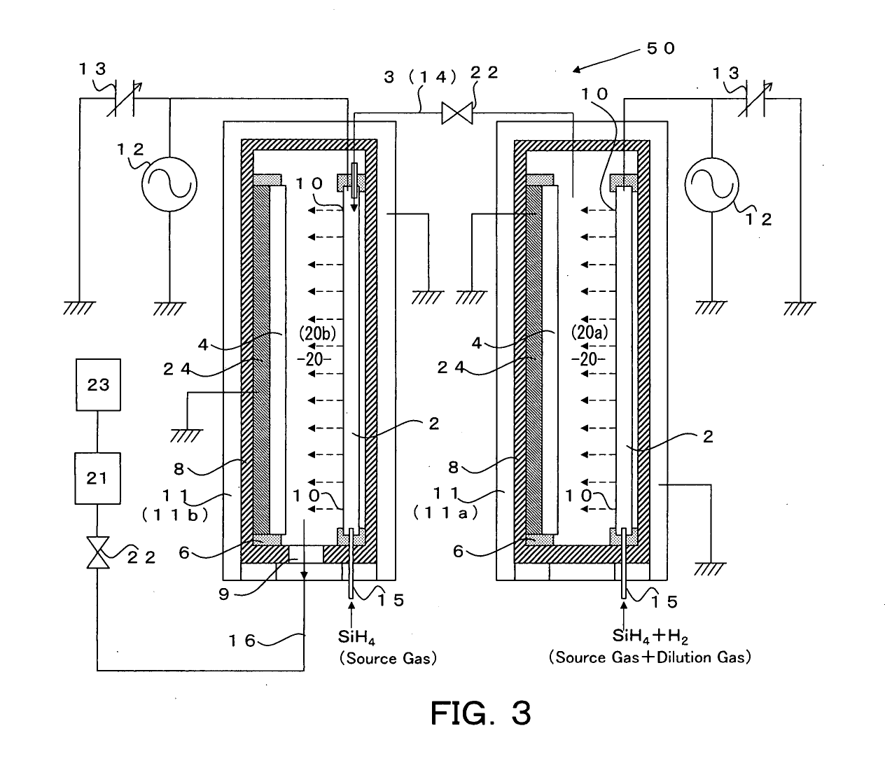

A third embodiment of a deposition apparatus of the invention will be described with reference to FIG. 3. FIG. 3 is a schematic vertical cross-sectional view of an inventive apparatus 50. Portions common to those in FIGS. 1 and 2 will be described using the same reference numerals.

Referring to FIG. 3, in the configuration of the inventive apparatus 50, thin-film formation spacings 20 are formed by separately providing discharge spacings each sandwiched by a cathode electrode 2 and an anode electrodes 4 in a plurality of chambers 11 (reaction chamber). Source-gas feed openings 10 are provided in each of the thin-film formation spacings 20. A discharge gas of the thin-film formation spacing 20 (first thin-film formation spacing 20a) of the chamber 11 (first chamber 11a) on one side is feedable into the thin-film formation spacing 20 (second thin-film formation spacing 20b) in the chamber 11 (second chamber 11b) on the other side through a discharge-gas flow path 14 (gas feed piping 3 for communicating between the individual chambers 11). In addition, in the configuration, a discharge gas of the second thin-film formation spacing 20b is discharged to the outside of the system from an external discharge port 9 provided in the second thin-film formation spacing 20b through discharge piping 16 via a pressure control unit 22, a vacuum pump 21, and a gas purification apparatus 23. A difference from the second embodiment is that the individual thin-film formation spacings 20 are formed in the chambers 11 (reaction chambers) independently of one another, and the basic configuration is common to that of the inventive apparatus 40 of the second embodiment.

Each of the chambers 11 is formed of stainless steel or an aluminium alloy. Connected or fitted portions of the chamber 11 are completely sealed by 0-rings or the like components. The gas feed piping 3 or the discharge piping 16 is connected to the chamber 11 to discharge the individual discharge gases from the chamber, and the pressure control unit 22 is interposed in each unit the piping, thereby enabling the vacuum level in the each individual chamber 11 to be controlled to an arbitrary level. However, the vacuum pump 21 is provided in the discharge piping 16 of the second chamber 11b. A large quantity of the discharge gas needs to be transferred to the cathode electrode 2 of the second chamber 11b, so that the gas feed piping 3 of the first chamber 11a should have a sufficient diameter and should be disposed to be shortest in the piping length. The gas purification apparatus 23 is connected to the downstream side of the vacuum pump 21 to remove deleterious substances contained in the discharge gas after reaction with the reactant gas (source gas) introduced into the each individual chamber 11.

The chambers 11 are each configured as follows. The anode electrode 4 is formed of a material having conductivity and heat resistance, such as stainless steel, aluminium alloy, or carbon. The size dimensions of the anode electrode 4 are determined to be appropriate values in accordance with the size dimensions of a glass substrate that used to form the thin film. In this particular embodiment, the anode electrode 4 is designed to have the size dimensions of (long side×short side: (1,000-1,500 mm)×(600-1,000 mm)) with respect to the size dimensions of the substrate of (900-1,200 mm)×(400-900 mm).

The anode electrode 4 has a built-in a heater 24 on the back face with respect to the thin-film formation spacing 20. Using the heater 24, the anode electrode 4 is heated and controlled to fall within the range of from a room temperature to 300° C. In the present embodiment, the anode electrode 4 uses a device consisting of, for example, an enclosed heating device, such as a sheath heater, and an enclosed temperature sensor, such as a thermocouple, which are built in the aluminium alloy. With these devices being used, the anode electrode 4 is heated and controlled to fall within the range of from the room temperature to 300° C.

The cathode electrode 2 has a function of a shower plate, in which a plurality of shower openings (source-gas feed openings 10) are distributed on the surface on the side opposite to the anode electrode 4. In this configuration, the source gas is fed to the cathode electrode 2 from a source gas inlet 15 provided to introduce the source gas into the cathode electrode 2 (shower plate) from the outside. Thereby, the introduced source gas can be uniformly dispersed and fed into the thin-film formation spacing 20 from the source-gas feed openings 10. In addition, the cathode electrode 2 is connected with a plasma-exciting high-frequency power source 12 and an impedance matching unit 13.

A gas mixture (SiH₄+H₂) of the source gas and the dilution gas is fed from the source gas inlet 15 to the shower plate 2 of the first chamber 11a. The discharge gas of the first chamber 11a is fed to the shower plate 2 of the second chamber 11b through the gas feed piping 3 (discharge-gas flow path 14).

Similar to the second embodiment illustrated in FIG. 2, the source gas (SiH₄ gas) is supplemented to the second thin-film formation spacing 20b for compensation. As such, the source gas inlet 15 is provided to the second chamber 11b to introduce the source gas from the outside into the cathode electrode 2 (shower plate). Thereby, a thin film identical to that formed in the first thin-film formation spacing 20a can be formed in the second thin-film formation spacing 20b of the second chamber 11b. In addition, the dilution gas in the first thin-film formation spacing 20a can be used also in the second thin-film formation spacing 20b, so that the use quantity of the dilution gas can be significantly reduced.

Another embodiment of a deposition apparatus of the invention will be described hereinbelow.

To simplify the description, while each of the individual embodiments has been described with reference to the configuration having two thin-film formation spacings 20, the number of the thin-film formation spacings 20 is not limited thereto. Also, the dimensions, materials, and the like in the individual portions are not limited to those of the individual above-described embodiments.

In each of the individual embodiments described above, suppose that three or more thin-film formation spacings 20 are provided. In this case, the configuration is preferably formed such that, as in the each individual embodiment described, individual thin-film formation spacings 20 are communicably series connected to one another through a discharge-gas flow path 14, and the spacing to which the dilution gas is introduced is limited to only one of the thin-film formation spacings 20. Further, also the spacing for discharging the discharge gas to the outside of the system through the external discharge port, the discharge piping 16, and the like is preferably limited to only one of the thin-film formation spacings 20. In the configuration thus arranged, the discharge gas of the one thin-film formation spacing 20 is fed into another one of the thin-film formation spacings 20 through the discharge-gas flow path 14. Thereby, similar to the each individual embodiment described above, the dilution gas can be shared also in the subsequent thin-film formation spacings 20. Consequently, even in a configuration with increased thin-film formation spacings 20 in number, the use quantity of the dilution gas need not be increased, therefore enabling the use quantity of the dilution gas to be significantly saved.

As described above, according to the deposition apparatus of the present invention, the quantity of the gases (especially, the dilution gas) to be consumed in the deposition apparatus can be significantly reduced. This consequently enables reducing the apparatus costs for the discharge system, the gas purification system, and the like, and enables obtaining semiconductor devices such as solar cells using either of semiconductor thin films or optical thin films, TFTs (thin-film transistors), photosensitive devices at low costs.

Although the present invention has been described in terms of preferred embodiments, it will be appreciated that various modifications and alterations might be made by those skilled in the art without departing from the spirit and scope of the invention. The invention should therefore be measured in terms of the appended claims.

1. A deposition apparatus comprising:
a plurality of thin-film formation spacings for forming same thin films, wherein:
source-gas feed openings capable of feeding at least a source gas are provided in each of the plurality of thin-film formation spacings; and
a discharge gas of at least one of the plurality of thin-film formation spacings can be fed into another one of the plurality of thin-film formation spacings.

2. The deposition apparatus of claim 1, wherein:
in addition to the source-gas feed openings, a dilution-gas feed port is provided in only one or a plurality of first thin-film formation spacings provided as a part of the plurality of thin-film formation spacings; and
the discharge gas of the first thin-film formation spacing can be fed into at least one of second thin-film formation spacings that is a part of the plurality of thin-film formation spacings and that is not the first thin-film formation spacing.

3. The deposition apparatus of claim 2, wherein an external discharge port for discharging the discharge gas to an external portion excluding the plurality of thin-film formation spacings is provided in at least one of the second thin-film formation spacings.

4. The deposition apparatus of claim 3, wherein:
one unit of the first thin-film formation spacing is provided; and
one unit of the second thin-film formation spacing is provided wherein the external discharge port is provided.

5. The deposition apparatus of claim 4, wherein in a case where the number of the plurality of thin-film formation spacings is three or more, the discharge gas of the second thin-film formation spacing wherein the external discharge port is not provided can be fed to another one of the second thin-film formation spacings.

6. The deposition apparatus of claim 1, wherein:
a dilution gas can be fed to source-gas feed openings of only one or the plurality of first thin-film formation spacings provided as a part of the plurality of thin-film formation spacings; and
the discharge gas of the first thin-film formation spacing can be fed into at least one of second thin-film formation spacings that is the part of the plurality of thin-film formation spacings and that is not the first thin-film formation spacing.

7. The deposition apparatus of claim 6, wherein an external discharge port for discharging the discharge gas to an external portion excluding the plurality of thin-film formation spacings is provided in at least one of the second thin-film formation spacings.

8. The deposition apparatus of claim 7, wherein:
one unit of the first thin-film formation spacing is provided; and
one unit, of the second thin-film formation spacing wherein the external discharge port is provided.

9. The deposition apparatus of claim 8, wherein in a case where the number of the plurality of thin-film formation spacings is three or more, the discharge gas of the second thin-film formation spacing wherein the external discharge port is not provided can be fed to another one of the second thin-film formation spacings.

10. The deposition apparatus of claim 1, wherein the source-gas feed openings are provided opposite a depositing plane in the form of plural distributions.

11. The deposition apparatus of claim 1, wherein each of the plurality of thin-film formation spacings is formed between a cathode electrode and an anode electrode that oppose each other.

12. The deposition apparatus of claim 11, wherein the source-gas feed openings are provided on the cathode electrode.

13. The deposition apparatus of claim 1, wherein the plurality of thin-film formation spacings are formed in one reaction chamber.

14. The deposition apparatus of claim 1, wherein each of the plurality of thin-film formation spacings is separately formed in one reaction chamber.

15. A deposition method for parallely forming same thin films in a plurality of thin-film formation spacings, the deposition method comprising:
feeding at least a source gas into each of the plurality of thin-film formation spacings; and
feeding a discharge gas of at least one of the plurality of thin-film formation spacings into another one of the plurality of thin-film formation spacings.

16. The deposition method of claim 15, further comprising:
in addition to the source gas, feeding a dilution gas into only one or a plurality of first thin-film formation spacings provided as a part of the plurality of thin-film formation spacings; and
feeding the discharge gas of the first thin-film formation spacing into at least one of second thin-film formation spacings that is a part of the plurality of thin-film formation spacings and that is not the first thin-film formation spacing.

17. The deposition method of claim 15, further comprising:
feeding a gas mixture of the source gas and a dilution gas into only one or a plurality of first thin-film formation spacings provided as a part of the plurality of thin-film formation spacings; and
feeding the discharge gas of the first thin-film formation spacing into at least one of second thin-film formation spacings that is a part of the plurality of thin-film formation spacings and that is not the first thin-film formation spacing.

18. The deposition method of claim 15, further comprising feeding the discharge gas of one or the plurality of first thin-film formation spacings into at least one of second thin-film formation spacings that is a part of the plurality of thin-film formation spacings and that is not the first thin-film formation spacing,
wherein a flow rate of a gas containing at least the source gas to be fed into the first thin-film formation spacing and a concentration of the source gas are different from the flow rate of a gas containing at least the source gas to be fed into a second thin-film formation spacing, to which the discharge gas of the first thin-film formation spacing is fed, and a concentration of the source gas.

19. The deposition method of claim 16, further comprising discharging the discharge gas from at least one of the second thin-film formation spacings to an external portion excluding the plurality of thin-film formation spacings.

20. The deposition method of claim 17, further comprising discharging the discharge gas from at least one of the second thin-film formation spacings to an external portion excluding the plurality of thin-film formation spacings.

21. The deposition method of claim 18, further comprising discharging the discharge gas from at least one of the second thin-film formation spacings to an external portion excluding the plurality of thin-film formation spacings.
